(19) United States
(12) Patent Application Publication
(10) Pub. No.: US 2011/0298642 A1
(43) Pub. Date: Dec. 8, 2011

(54) CURRENT TRIMMING CIRCUIT AND A/D CONVERTER INCLUDING CURRENT TRIMMING CIRCUIT

(75) Inventors: Daisuke NOMASAKI, Osaka (JP); Takeshi OKUMOTO, Hyogo (JP)

(73) Assignee: PANASONIC CORPORATION, Osaka (JP)

(21) Appl. No.: 13/210,863

(22) Filed: Aug. 16, 2011

Related U.S. Application Data
(63) Continuation of application No. PCT/JP2009/003481, filed on Jul. 23, 2009.

(30) Foreign Application Priority Data
Mar. 5, 2009 (JP) 2009-051768

(51) Int. Cl. H03M 1/10; H03K 17/687

(52) U.S. Cl. 341/121; 327/103

(57) ABSTRACT

A current is generated from a reference voltage using an operational amplifier. The current is mirrored by a current mirror circuit to obtain a reference current. For example, the current mirror circuit includes a plurality of PMOS transistors. Based on the result of measurement of the reference current by an external monitor, the connection destination of the gate voltage of each of a plurality of mirror destination current source transistors is switched by an analog switch circuit between a power supply and the gate of a mirror source current source transistor, thereby changing the number of mirror destination current source transistors which are turned on, to change a current minor ratio. Thus, the current can be trimmed.

### CROSS-REFERENCE TO RELATED APPLICATIONS

This is a continuation of PCT International Application PCT/JP2009/003481 filed on Jul. 23, 2009, which claims priority to Japanese Patent Application No. 2009-051768 filed on Mar. 5, 2009. The disclosures of these applications including the specifications, the drawings, and the claims are hereby incorporated by reference in their entirety.

### BACKGROUND

The present disclosure relates to current trimming circuits which output an internally generated current and trim the current based on the result of measurement of the current.

A conventional current trimming circuit includes a reference voltage generation circuit, an operational amplifier which amplifies the generated reference voltage, a transistor which receives the voltage output from the operational amplifier, a resistor ladder which is connected in series to the transistor, an analog switch circuit which selectively feeds a tap thereof back to an input terminal of the operational amplifier, a trimming circuit which controls the operation of the analog switch circuit, and an I/O pad which allows a current flowing through the resistor ladder to be externally monitored. The current is measured at the I/O pad, and based on the result of the measurement, a feedback path from the resistor ladder to the input of the operational amplifier is changed by the trimming circuit, whereby the current is trimmed (see Japanese Patent Publication No. H11-346127).

In the conventional current trimming circuit, the value of the current is measured outside the circuit, and based on the result of the measurement, the resistance value of the reference resistor is changed, whereby the current value is trimmed. The circuit is implemented by disposing a plurality of unit resistors corresponding to a trimming step on a semiconductor substrate. However, there is a large deviation of the resistance value of the resistor provided on the semiconductor substrate from the desired value, which occurs during fabrication due to the accuracy of fabrication. Therefore, in order to set a desired trimming range, it is necessary to reduce the deviation of the resistance value by increasing the area of the unit resistor. Such a structure leads to an increase in the area, which poses a problem in reducing the area.

### SUMMARY

The present disclosure describes implementations of a current trimming circuit having a small area and high accuracy and an A/D converter including the current trimming circuit.

In the present disclosure, in order to achieve the object, the mirror ratio of a current mirror circuit included in a reference current circuit is changed instead of changing the resistance value of a reference resistance based on the result of measurement of the current value. In this case, a plurality of rows of mirror circuits are provided on a semiconductor substrate. However, the area of the mirror circuits can be smaller than that which is required when a plurality of reference resistors are provided on the semiconductor substrate.

Alternatively, in the present disclosure, in order to achieve the object, a second reference voltage which is obtained by resistively dividing a first reference voltage is changed instead of changing the resistance value of a reference resistance based on the result of measurement of the current value. In this case, although voltage-dividing resistors are provided on a semiconductor substrate, a deviation of the resistance value which occurs during fabrication of the voltage-dividing resistors only has an influence as a relative deviation of the second reference voltage. Therefore, the area of the voltage-dividing resistors can be reduced to the extent possible, i.e., can be smaller than that which is required when a plurality of reference resistors are provided on the semiconductor substrate.

According to the present disclosure, a current mirrored by a plurality of current mirror circuits connected together in parallel is externally measured, and based on the result of the measurement, the gate voltages of the current mirror circuits are controlled to change the mirror ratio of the current mirror circuits, thereby obtaining a desired current value. Therefore, the area of the current mirror circuits can be smaller than that which is required when a plurality of reference resistors are provided on the semiconductor substrate. Also, trimming is performed on the mirrored current value, whereby variations in current caused by the mirror circuit can be reduced, resulting in a current trimming circuit which provides a highly accurate current.

According to the present disclosure, a current mirrored by a current mirror circuit is externally measured, and based on the result of the measurement, a second reference voltage which is obtained from a first reference voltage by resistive division is changed, thereby obtaining a desired value. Therefore, the area of the current mirror circuit can be smaller than that which is required when a plurality of reference resistors are provided on the semiconductor substrate. Also, trimming is performed on the mirrored current value, whereby variations in current caused by the mirror circuit can be reduced, resulting in a current trimming circuit which provides a highly accurate current.

### BRIEF DESCRIPTION OF THE DRAWINGS

FIG. 1 is a circuit diagram of a current trimming circuit according to a first embodiment of the present disclosure.

FIG. 2 is a flowchart of a current trimming step in the first embodiment of the present disclosure.

FIG. 3 is a circuit diagram of a current trimming circuit according to a first variation of the first embodiment of the present disclosure.

FIG. 4 is a circuit diagram of a current trimming circuit according to a second variation of the first embodiment of the present disclosure.

FIG. 5 is a circuit diagram of a current trimming circuit according to a third variation of the first embodiment of the present disclosure.

FIG. 6 is a circuit diagram of a current trimming circuit according to a fourth variation of the first embodiment of the present disclosure.

FIG. 7 is a circuit diagram of a current trimming circuit according to a fifth variation of the first embodiment of the present disclosure.

FIG. 8 is a circuit diagram of a current trimming circuit according to a sixth variation of the first embodiment of the present disclosure.

FIG. 9 is a circuit diagram of a current trimming circuit according to a seventh variation of the first embodiment of the present disclosure.

FIG. 10 is a circuit diagram of a current trimming circuit according to an eighth variation of the first embodiment of the present disclosure.

FIG. 11 is a circuit diagram of a current trimming circuit according to a second embodiment of the present disclosure.

FIG. 12 is a circuit diagram of an A/D converter including a current trimming circuit according to a third embodiment of the present disclosure.

### DETAILED DESCRIPTION

Embodiments of the present disclosure will be described hereinafter with reference to the accompanying drawings.

### First Embodiment

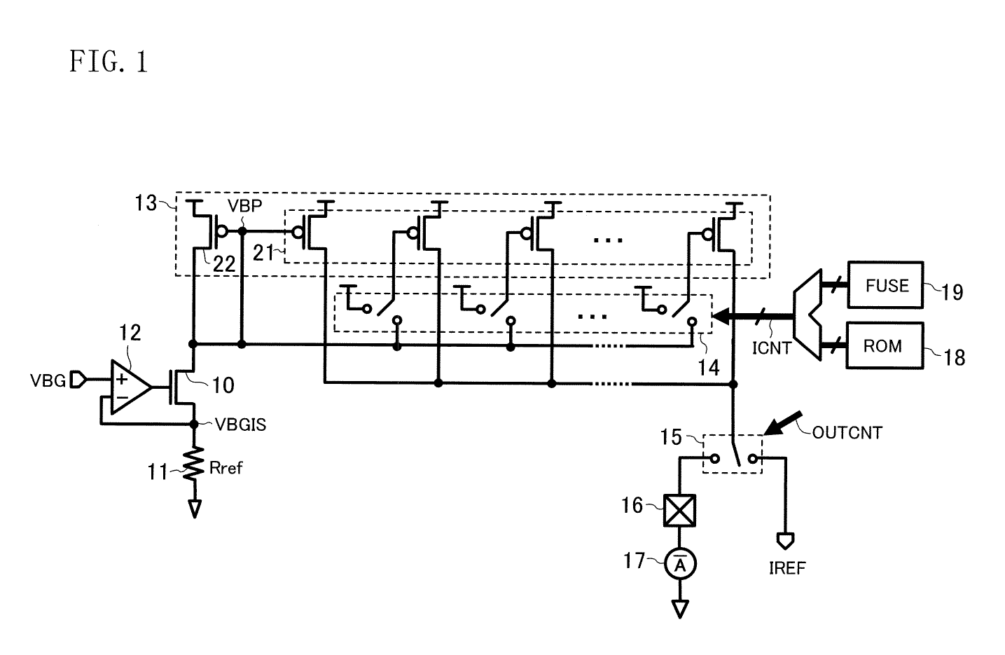

FIG. 1 is a circuit diagram showing a current trimming circuit according to a first embodiment of the present disclosure. A highly accurate reference voltage VBG generated by, for example, a band-gap reference circuit is input to the current trimming circuit. A current is generated from a voltage VBGIS which is virtually short-circuited to the reference voltage VBG using an operational amplifier 12, and a resistor 11 having a resistance value Rref, using an NMOS transistor 10. The current is mirrored by a current mirror circuit 13 which includes a plurality of transistors connected together in parallel to obtain a reference current IREF. The connection destination of the gate voltage of each of mirror destination PMOS current source transistors 21 included in the current mirror circuit 13 can be switched between the gate voltage VBP of a mirror source PMOS current source transistor 22 and a power supply, by controlling an analog switch circuit 14 based on a control signal ICNT, whereby the value of the reference current IREF can be arbitrarily set. Specifically, the current mirror ratio is changed by changing the number of ones of the mirror destination PMOS current source transistors 21 which are turned on, using the analog switch circuit 14. The reference current IREF is normally supplied to an analog circuit, such as an operational amplifier etc. During testing, an analog switch 15 is switched based on an output control signal OUTCNT so that the reference current IREF is output from the current trimming circuit via an I/O pad 16.

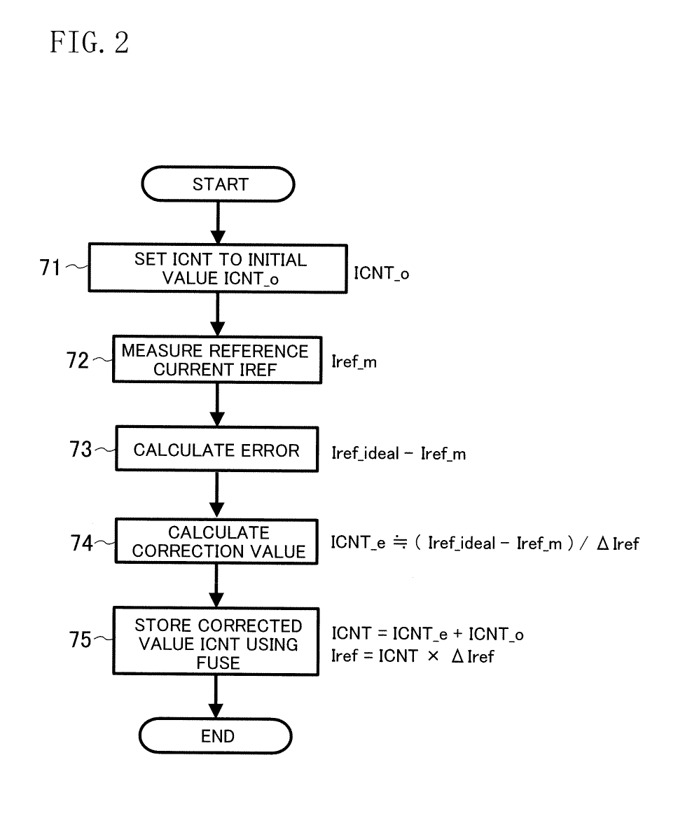

FIG. 2 is a flowchart showing a current trimming step according to the first embodiment of the present disclosure. Initially, an initial value ICNT_o of the control signal ICNT corresponding to an initial value of the reference current IREF is read from a ROM 18 to set a state of the analog switch circuit 14 (initial value setting step 71), and the reference current IREF output from the current trimming circuit is externally measured using a current measuring device 17, such as a tester etc. (measurement step 72). An error between the result Iref_m of the measurement and a desired value Iref_ideal is calculated (calculation step 73), and a correction value ICNT_e is calculated from the error using a coefficient ΔIref so that the reference current IREF has a desired value (calculation step 74). If the set value of the corrected control signal ICNT is stored in a fuse 19 (fuse cutting step 75), then even when the original reference current IREF varies due to the resistance variations, the reference current IREF of each chip can be trimmed during testing so that a highly accurate reference current IREF is supplied to the analog circuit. The set value of the corrected control signal ICNT may be stored in a non-volatile memory instead of the fuse 19.

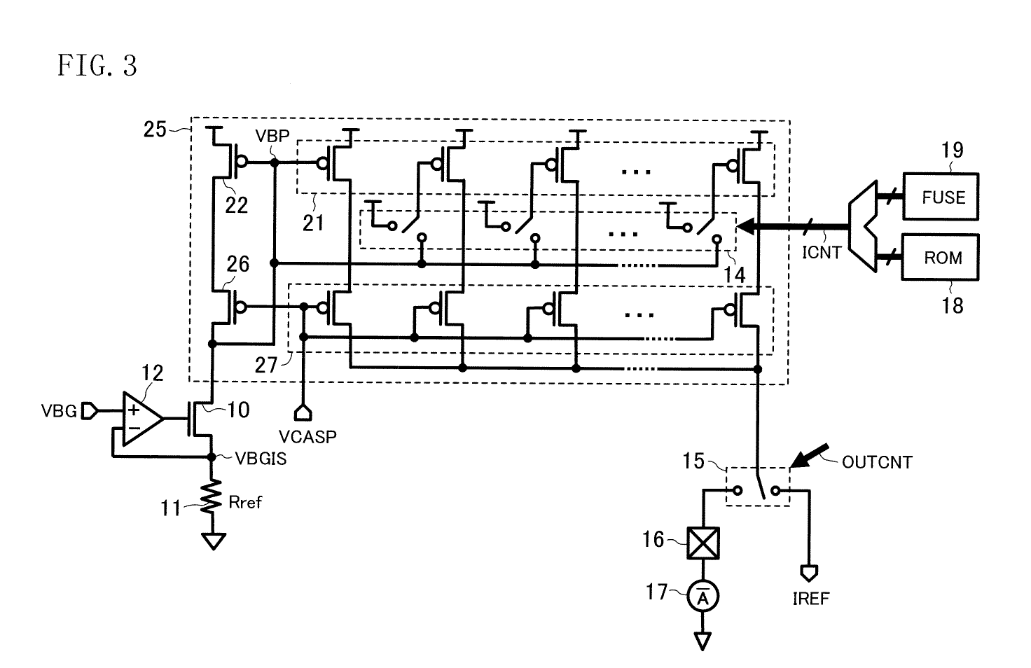

FIG. 3 is a circuit diagram showing a current trimming circuit according to a first variation of the first embodiment of the present disclosure. A current mirror circuit 25 includes a cascode current source. In the current mirror circuit 25, PMOS cascode transistors 26 and 27 are provided in current paths of PMOS current source transistors 22 and 21 (a mirror source and a mirror destination), respectively, whereby the accuracy of current mirror is increased. A common cascode voltage VCASP is supplied to the gates of the PMOS cascode transistors 26 and 27. Compared to the configuration of FIG. 1, the accuracy of the reference current IREF is improved by the addition of the PMOS cascode transistors 26 and 27.

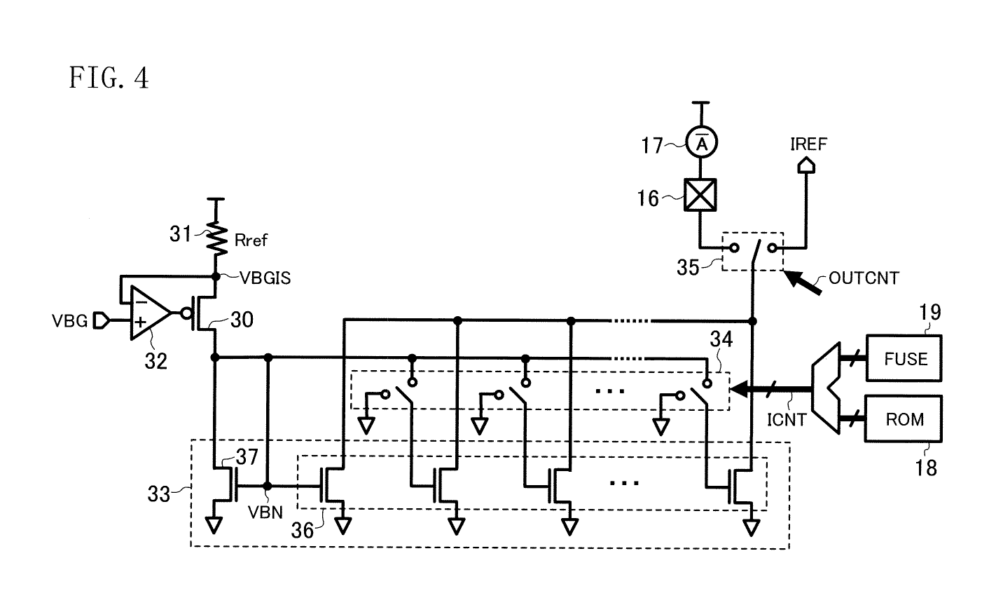

FIG. 4 is a circuit diagram showing a current trimming circuit according to a second variation of the first embodiment of the present disclosure. The reference voltage VBG is input to the current trimming circuit. A current is generated from a voltage VBGIS which is virtually short-circuited to the reference voltage VBG using an operational amplifier 32, and a resistor 31 having a resistance value Rref, using a PMOS transistor 30. The current is mirrored by a current mirror circuit 33 which includes a plurality of transistors connected together in parallel to obtain a reference current IREF. The connection destination of the gate voltage of each of mirror destination NMOS current source transistors 36 included in the current mirror circuit 33 can be switched between the gate voltage VBN of a mirror source NMOS current source transistor 37 and a ground, by controlling an analog switch circuit 34 based a control signal ICNT, whereby the value of the reference current IREF can be arbitrarily set. The reference current IREF is normally supplied to an analog circuit, such as an operational amplifier etc. During testing, an analog switch 35 is switched based on an output control signal OUTCNT so that the reference current IREF is output from the current trimming circuit via an I/O pad 16. The reference current IREF output from the current trimming circuit is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the analog circuit.

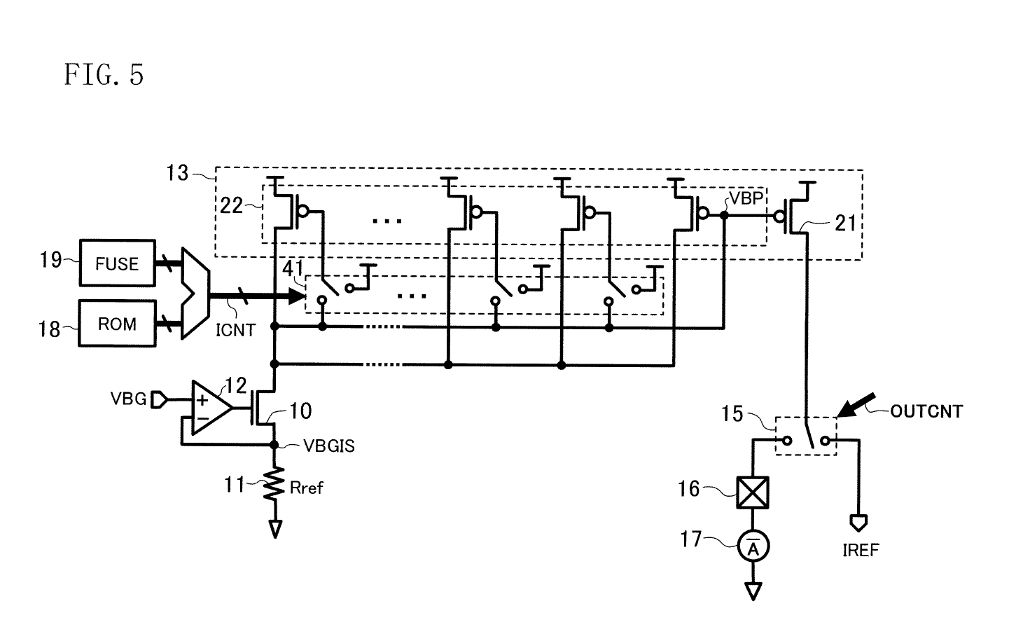

FIG. 5 is a circuit diagram showing a current trimming circuit according to a third variation of the first embodiment of the present disclosure. The reference voltage VBG is input to the current trimming circuit. A current is generated from a voltage VBGIS which is virtually short-circuited to the reference voltage VBG using an operational amplifier 12, and a resistor 11 having a resistance value Rref, using an NMOS transistor 10. The current is mirrored by a current mirror circuit 13 which includes a plurality of transistors connected together in parallel to obtain a reference current IREF. The connection destination of the gate voltage of each of mirror source PMOS current source transistors 22 included in the current mirror circuit 13 can be switched between the gate voltage VBP of a mirror destination PMOS current source transistor 21 and a power supply, by controlling an analog switch circuit 41 based a control signal ICNT, whereby the value of the reference current IREF can be arbitrarily set. The reference current IREF is normally supplied to an analog circuit, such as an operational amplifier etc. During testing, an analog switch 15 is switched based on an output control signal OUTCNT so that the reference current IREF is output from the current trimming circuit via an I/O pad 16. The reference current IREF output from the current trimming circuit is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the analog circuit.

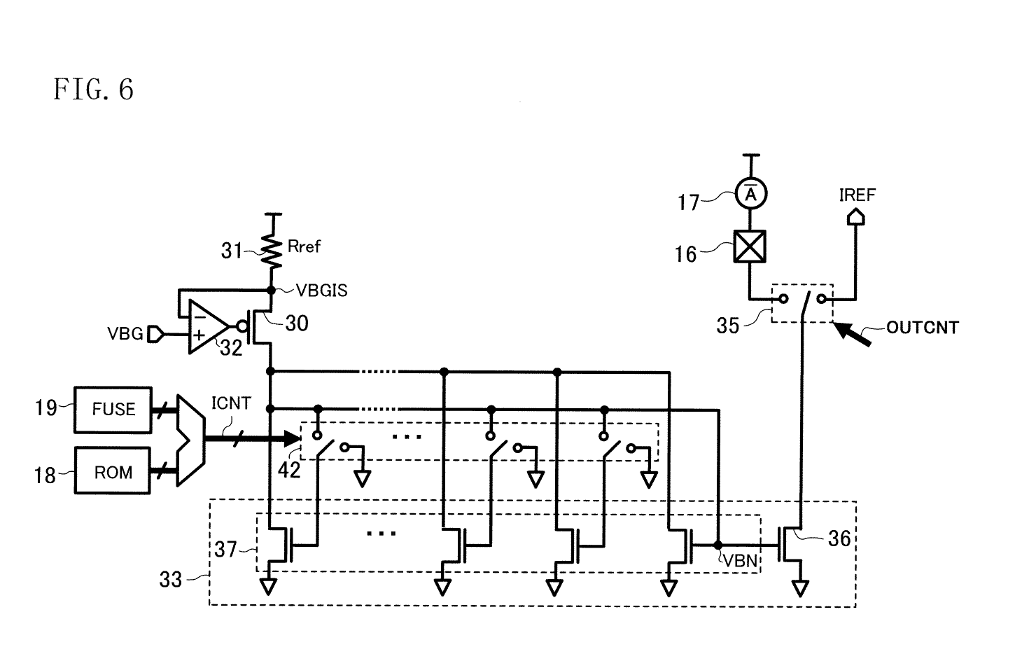

FIG. 6 is a circuit diagram showing a current trimming circuit according to a fourth variation of the first embodiment of the present disclosure. The reference voltage VBG is input to the current trimming circuit. A current is generated from a voltage VBGIS which is virtually short-circuited to the reference voltage VBG using an operational amplifier 32, and a resistor 31 having a resistance value Rref, using a PMOS transistor 30. The current is mirrored by a current mirror circuit 33 which includes a plurality of transistors connected together in parallel to obtain a reference current IREF. The connection destination of the gate voltage of each of mirror source NMOS current source transistors 37 included in the current mirror circuit 33 can be switched between the gate voltage VBN of a mirror destination NMOS current source transistor 36 and a ground, by controlling an analog switch circuit 42 based a control signal ICNT, whereby the value of the reference current IREF can be arbitrarily set. The reference current IREF is normally supplied to an analog circuit, such as an operational amplifier etc. During testing, an analog switch 35 is switched based on an output control signal OUTCNT so that the reference current IREF is output from the current trimming circuit via an I/O pad 16. The reference current IREF output from the current trimming circuit is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the analog circuit.

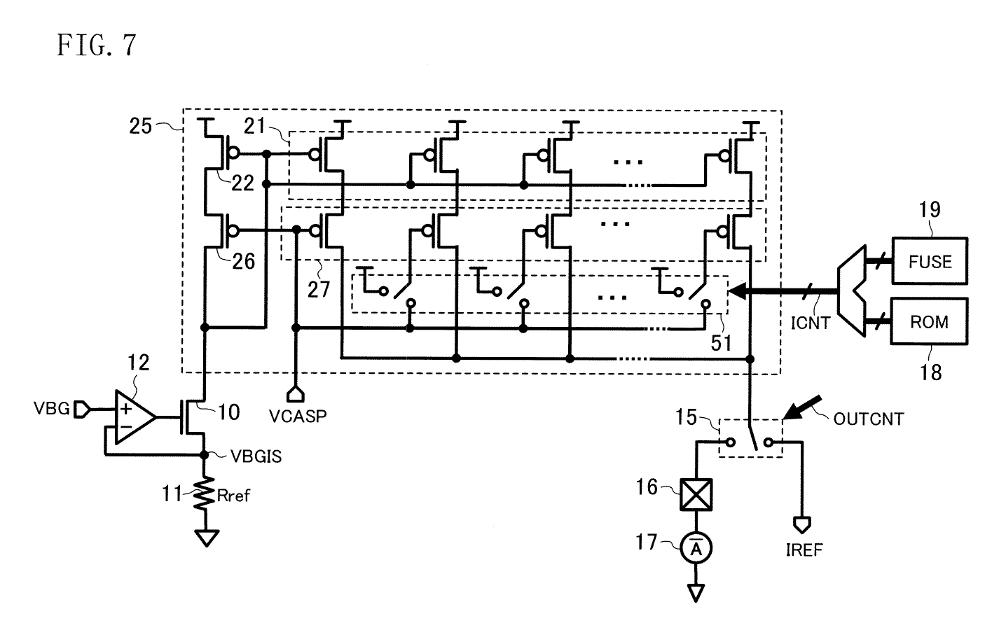

FIG. 7 is a circuit diagram showing a current trimming circuit according to a fifth variation of the first embodiment of the present disclosure. The reference voltage VBG is input to the current trimming circuit. A current is generated from a voltage VBGIS which is virtually short-circuited to the reference voltage VBG using an operational amplifier 12, and a resistor 11 having a resistance value Rref, using an NMOS transistor 10. The current is mirrored by a current mirror circuit 25 which includes a plurality of transistors connected together in parallel to obtain a reference current IREF. The current mirror circuit 25 includes a cascode current source. In the current mirror circuit 25, PMOS cascode transistors 26 and 27 are provided in current paths of PMOS current source transistors 22 and 21 (a mirror source and a mirror destination), respectively, whereby the accuracy of current mirror is increased. The connection destination of the gate voltage of each of mirror destination PMOS cascode current source transistors 27 included in the current mirror circuit 25 can be switched between a cascode voltage VCASP and a power supply, by controlling an analog switch circuit 51 based a control signal ICNT, whereby the value of the reference current IREF can be arbitrarily set. The reference current IREF is normally supplied to an analog circuit, such as an operational amplifier etc. During testing, an analog switch 15 is switched based on an output control signal OUTCNT so that the reference current IREF is output from the current trimming circuit via an I/O pad 16. The reference current IREF output from the current trimming circuit is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the analog circuit.

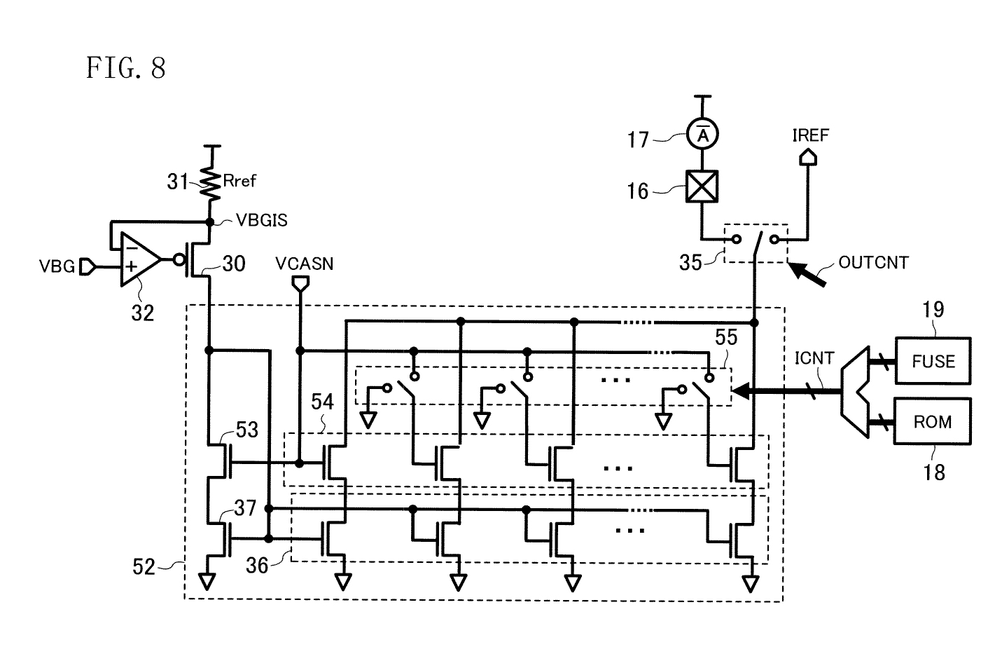

FIG. 8 is a circuit diagram showing a current trimming circuit according to a sixth variation of the first embodiment of the present disclosure. The reference voltage VBG is input to the current trimming circuit. A current is generated from a voltage VBGIS which is virtually short-circuited to the reference voltage VBG using an operational amplifier 32, and a resistor 31 having a resistance value Rref, using a PMOS transistor 30. The current is mirrored by a current mirror circuit 52 which includes a plurality of transistors connected together in parallel to obtain a reference current IREF. The current mirror circuit 52 includes a cascode current source. In the current mirror circuit 52, NMOS cascode transistors 53 and 54 are provided in current paths of NMOS current source transistors 37 and 36 (a mirror source and a mirror destination), respectively, whereby the accuracy of current mirror is increased. The connection destination of the gate voltage of each of mirror destination NMOS cascode current source transistors 54 included in the current mirror circuit 52 can be switched between a cascode voltage VCASN and a ground, by controlling an analog switch circuit 55 based a control signal ICNT, whereby the value of the reference current IREF can be arbitrarily set. The reference current IREF is normally supplied to an analog circuit, such as an operational amplifier etc. During testing, an analog switch 35 is switched based on an output control signal OUTCNT so that the reference current IREF is output from the current trimming circuit via an I/O pad 16. The reference current IREF output from the current trimming circuit is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the analog circuit.

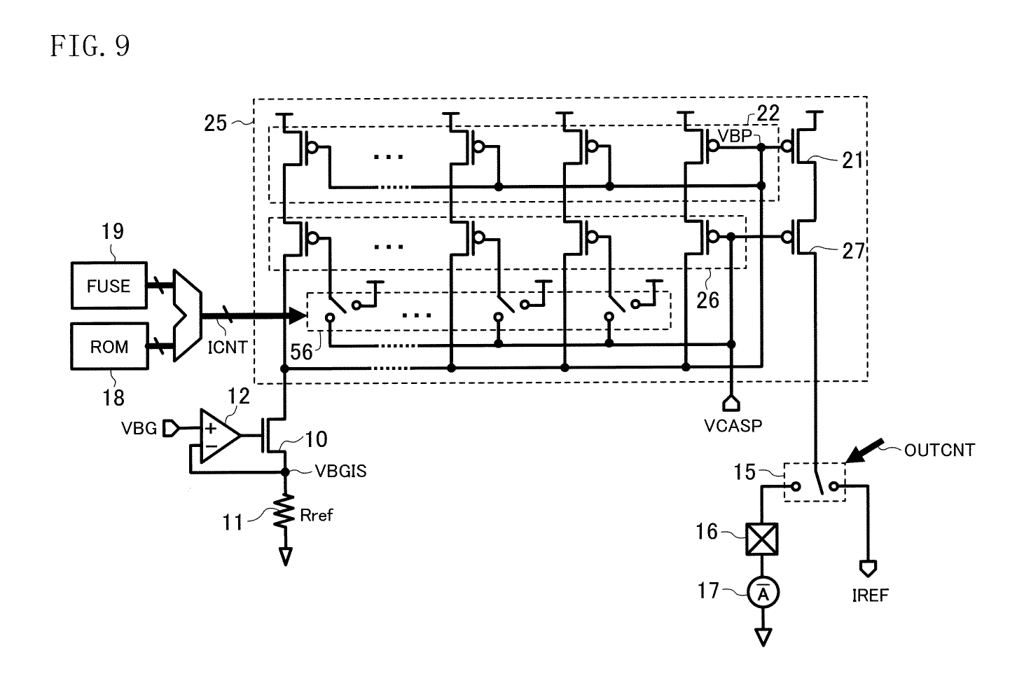

FIG. 9 is a circuit diagram showing a current trimming circuit according to a seventh variation of the first embodiment of the present disclosure. The reference voltage VBG is input to the current trimming circuit. A current is generated from a voltage VBGIS which is virtually short-circuited to the reference voltage VBG using an operational amplifier 12, and a resistor 11 having a resistance value Rref, using an NMOS transistor 10. The current is mirrored by a current mirror circuit 25 which includes a plurality of transistors connected together in parallel to obtain a reference current IREF. The current mirror circuit 25 includes a cascode current source. In the current mirror circuit 25, PMOS cascode transistors 26 and 27 are provided in current paths of PMOS current source transistors 22 and 21 (a mirror source and a mirror destination), respectively, whereby the accuracy of current mirror is increased. The connection destination of the gate voltage of each of mirror source PMOS cascode current source transistors 26 included in the current mirror circuit 25 can be switched between a cascode voltage VCASP and a power supply, by controlling an analog switch circuit 56 based a control signal ICNT, whereby the value of the reference current IREF can be arbitrarily set. The reference current IREF is normally supplied to an analog circuit, such as an operational amplifier etc. During testing, an analog switch 15 is switched based on an output control signal OUTCNT so that the reference current IREF is output from the current trimming circuit via an I/O pad 16. The reference current IREF output from the current trimming circuit is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the analog circuit.

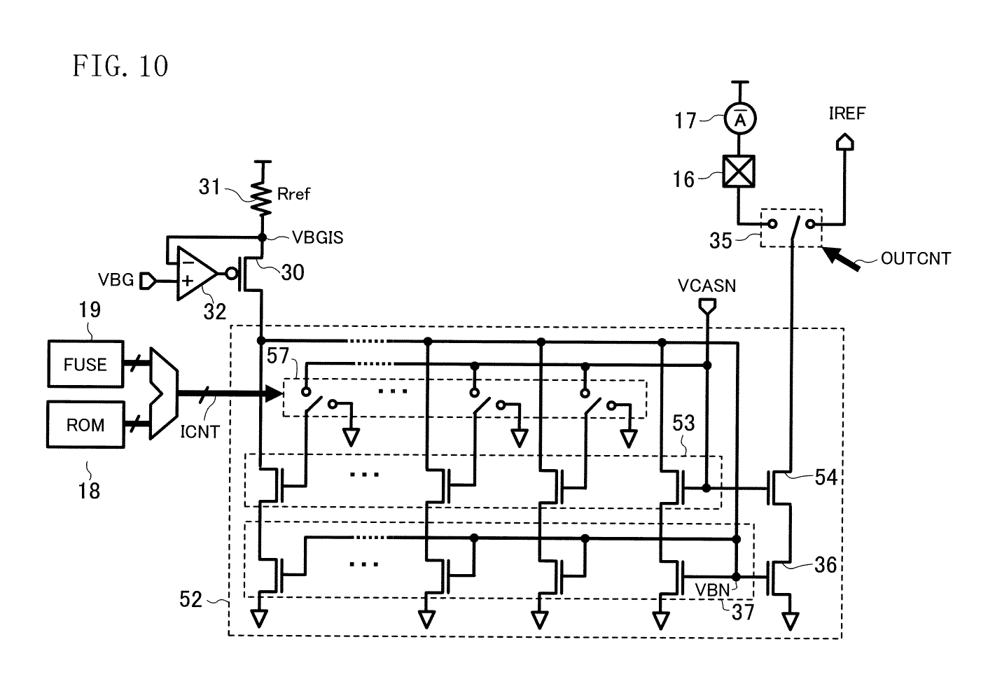

FIG. 10 is a circuit diagram showing a current trimming circuit according to an eighth variation of the first embodiment of the present disclosure. The reference voltage VBG is input to the current trimming circuit. A current is generated from a voltage VBGIS which is virtually short-circuited to the reference voltage VBG using an operational amplifier 32, and a resistor 31 having a resistance value Rref, using a PMOS transistor 30. The current is mirrored by a current mirror circuit 52 which includes a plurality of transistors connected together in parallel to obtain a reference current IREF. The current mirror circuit 52 includes a cascode current source. In the current mirror circuit 52, NMOS cascode transistors 53 and 54 are provided in current paths of NMOS current source transistors 37 and 36 (a mirror source and a mirror destination), respectively, whereby the accuracy of current mirror is increased. The connection destination of the gate voltage of each of mirror source NMOS cascode current source transistors 53 included in the current mirror circuit 52 can be switched between a cascode voltage VCASN and a ground, by controlling an analog switch circuit 57 based a control signal ICNT, whereby the value of the reference current IREF can be arbitrarily set. The reference current IREF is normally supplied to an analog circuit, such as an operational amplifier etc. During testing, an analog switch 35 is switched based on an output control signal OUTCNT so that the reference current IREF is output from the current trimming circuit via an I/O pad 16. The reference current IREF output from the current trimming circuit is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the analog circuit.

### Second Embodiment

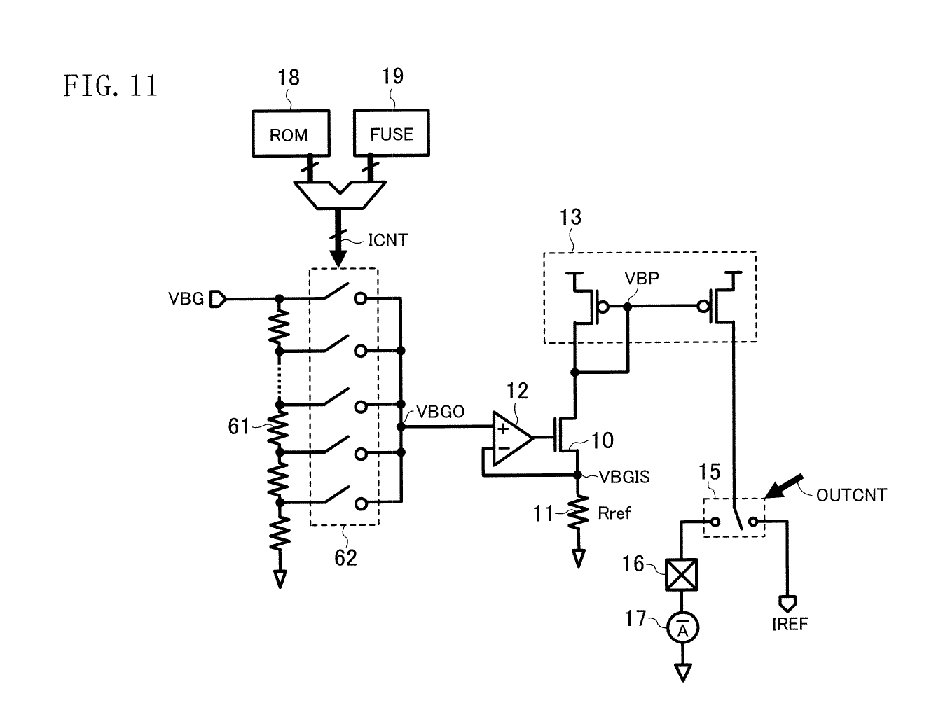

FIG. 11 is a circuit diagram showing a current trimming circuit according to a second embodiment of the present disclosure. A reference voltage VBGO is input to the current trimming circuit. A current is generated from a voltage VBGIS which is virtually short-circuited to the reference voltage VBGO using an operational amplifier 12, and a resistor 11 having a resistance value Rref, using an NMOS transistor 10. The current is mirrored by a current mirror circuit 13. The reference voltage VBGO is a voltage which is obtained by resistively dividing, using a resistor ladder 61, a highly accurate reference voltage VBG generated by, for example, a band-gap reference circuit, and can be switched by controlling an analog switch circuit 62 based a control signal ICNT, whereby the value of the reference current IREF can be arbitrarily set. The reference current IREF is normally supplied to an analog circuit, such as an operational amplifier etc. During testing, an analog switch 15 is switched based on an output control signal OUTCNT so that the reference current IREF is output from the current trimming circuit via an I/O pad 16. The reference current IREF output from the current trimming circuit is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the analog circuit. The set value of the corrected control signal ICNT may be stored in a non-volatile memory instead of the fuse 19.

### Third Embodiment

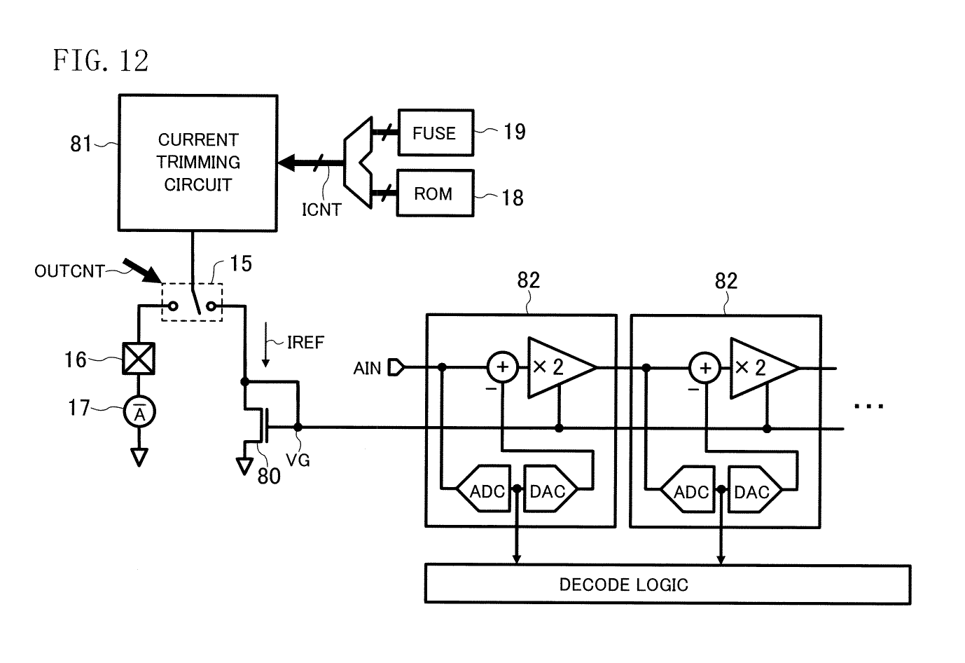

FIG. 12 is a circuit diagram showing an A/D converter including a current trimming circuit according to a third embodiment of the present disclosure. An output of the current trimming circuit 81 according to any of the first embodiment (including its variations) and the second embodiment is connected to an analog switch 15. The analog switch 15 switches, based on an output control signal OUTCNT, the destination of the output of the current trimming circuit 81 between an I/O pad 16 and an A/D converter core 82 which processes an analog input AIN. The value of the reference current IREF can be arbitrarily controlled and set based on a control signal ICNT. The reference current IREF is normally supplied as an operating voltage VG via an NMOS transistor 80 to the A/D converter core 82. During testing, the analog switch 15 is switched based on the output control signal OUTCNT so that the reference current IREF is output from the A/D converter via the I/O pad 16. The reference current IREF output from the A/D converter is externally measured using a current measuring device 17, such as a tester etc. If the result of the measurement is deviated from a desired value, the control signal ICNT can be arbitrarily changed and set so that the reference current IREF has the desired value. If the set value thus obtained is stored in a fuse 19, then even when the original reference current IREF varies due to the resistance variations, the reference current IREF of each chip can be trimmed during testing so that a highly accurate reference current IREF is supplied to the A/D converter core 82 as an operating current for the A/D converter core 82.

As described above, in the current trimming circuit of the present disclosure and the A/D converter including the current trimming circuit, even if the original reference current varies due to the resistance variations, the reference current to each chip is trimmed during testing by changing the mirror ratio of a current mirror circuit or a reference voltage, whereby a highly accurate current can be supplied to an analog circuit. Thus, a current trimming circuit which can provide a highly accurate current, and an A/D converter including the current trimming circuit, can be implemented using a smaller area than that which is conventionally required when a reference resistance is trimmed. The present disclosure is useful for semiconductor integrated circuits including both analog and digital systems, e.g., highly accurate and lower-cost processing, such as video signal processing in cameras, televisions, camcorders, etc., communication signal processing in wireless LAN etc., and digital read processing in DVDs etc.

What is claimed is:

1. A current trimming circuit for inputting a trimmed current to an internal circuit driven by the input current, comprising:
a voltage-to-current conversion circuit configured to convert an input voltage into a current;
a current mirror circuit including a plurality of transistors connected together in parallel and configured to receive the current obtained by the conversion and output a mirrored version of the received current;
an external terminal connectable to an external monitor for measuring a current value;
a switch configured to input the output current of the current mirror circuit to the external terminal or the internal circuit; and
a control circuit configured to switch connections of gates of the transistors included in the current mirror circuit to trim the output current of the current mirror circuit, wherein
based on a result of measurement obtained when the external terminal is connected to the external monitor, the current trimmed by the control circuit is input via the switch to the internal circuit.

2. The current trimming circuit of claim 1, wherein
the control circuit includes an analog switch circuit configured to switch the connections of the gate voltages of the transistors included in the current mirror circuit.

3. The current trimming circuit of claim 2, wherein
the control circuit further includes a circuit configured to set the analog switch circuit to an initial state.

4. The current trimming circuit of claim 2, wherein
the control circuit further includes a circuit configured to store a state of the analog switch circuit which provides a current mirror ratio changed based on the result of the measurement.

5. The current trimming circuit of claim 1, wherein
the current mirror circuit includes a mirror source circuit including a transistor whose gate and drain are connected together, and a mirror destination circuit including a plurality of transistors which are connected together in parallel, with drains thereof being connected together, and the current obtained by the conversion is passed to the drains of the transistors included in the mirror source circuit, whereby a voltage equal to or different from a voltage of the gates of the transistors included in the mirror source circuit is input to the gates of the transistors included in the mirror destination circuit, thereby changing the current mirror ratio.

6. The current trimming circuit of claim 5, wherein
the transistors included in the current mirror circuit are PMOS transistors, and the gate of each of the mirror destination transistors connected together in parallel is connected to the gate of the mirror source transistor or a power supply, thereby changing the current mirror ratio.

7. The current trimming circuit of claim 1, wherein
the current mirror circuit includes a mirror source circuit including a mirror source transistor whose gate and drain are connected together and a plurality of transistors which are connected together in parallel, with drains thereof being connected to the drain of the mirror source transistor, and a mirror destination circuit including a transistor whose gate is connected to the gate of the mirror source transistor, and the current obtained by the conversion is passed to the drain of the mirror source transistor or the drains of the plurality of transistors, whereby a voltage equal to or different from a voltage of the gate of the mirror source transistor is input to the gates of the plurality of transistors included in the mirror source circuit, thereby changing the current mirror ratio.

8. The current trimming circuit of claim 7, wherein
the transistors included in the current mirror circuit are PMOS transistors, and the gates of each of the plurality of transistors connected together in parallel in the mirror source circuit is connected to the gate of the minor source transistor or a power supply, thereby changing the current mirror ratio.

9. The current trimming circuit of claim 1, wherein
the current mirror circuit includes a mirror source circuit including a first and a second transistor connected together in cascode, a gate of the first transistor being connected to a drain of the second transistor, and a mirror destination circuit including a plurality of cascode connection circuits each including a first and a second transistor connected together in cascode, the second transistors being connected together in parallel, with gates thereof being connected together and drains thereof being connected together, and the current obtained by the conversion is passed to the drain of the second transistor of the mirror source circuit, and a voltage equal to or different from a voltage of the gate of the first transistor of the mirror source circuit is input to the gate of each of the first transistors of the mirror destination circuit, thereby changing the current mirror ratio.

10. The current trimming circuit of claim 9, wherein
the transistors included in the current mirror circuit are PMOS transistors, and the gate of each of the first transistors of the plurality of cascode connection circuits in the mirror destination circuit is connected to the gate of the first transistor of the mirror source circuit or a power supply, thereby changing the current mirror ratio.

11. The current trimming circuit of claim 1, wherein
the current mirror circuit includes a mirror source circuit including a first cascode connection circuit including a first and a second transistor connected together in cascode, a gate of the first transistor being connected to a drain of the second transistor, and a plurality of second cascode connection circuits each including a first and a second transistor connected together in cascode, the first transistors being connected together in parallel, with gates thereof being connected together and drains thereof being connected together, and a mirror destination circuit including a first and a second transistor connected together in cascode, a gate of the first transistor being connected to the gate of the first transistor of the first cascode connection circuit, and a gate of the second transistor being connected to a gate of the second transistor of the first cascode connection circuit, and the current obtained by the conversion is passed to the drain of the second transistor of the first cascode connection circuit of the mirror source circuit or the drains of the second transistors of the plurality of second cascode connection circuits of the mirror source circuit, and a voltage equal to or different from a voltage of the gate of the second transistor of the first cascode connection circuit of the mirror source circuit is input to the gates of the plurality of second transistors of the mirror source circuit, thereby changing the current mirror ratio.

12. The current trimming circuit of claim 11, wherein
the transistors included in the current mirror circuit are PMOS transistors, and the gate of each of the second transistors of the plurality of second cascode connection circuits in the mirror source circuit is connected to the gate of the second transistor of the first cascode connection circuit of the mirror source circuit or a power supply, thereby changing the current mirror ratio.

13. An A/D converter driven by an input trimmed current, comprising:
a voltage-to-current conversion circuit configured to convert an input voltage into a current;
a current mirror circuit including a plurality of transistors connected together in parallel and configured to receive the current obtained by the conversion and output a mirrored version of the received current;
an A/D conversion circuit;
an external terminal connectable to an external monitor for measuring a current value;
a switch configured to input the output current of the current mirror circuit to the external terminal or the A/D conversion circuit; and
a control circuit configured to switch connections of gates of the transistors included in the current mirror circuit to trim the output current of the current mirror circuit, wherein
based on a result of measurement obtained when the external terminal is connected to the external monitor, the current trimmed by the control circuit is input via the switch to the A/D conversion circuit.
